(19) United States
(12) Patent Application Publication
(10) Pub. No.: US 2021/0028221 A1
(43) Pub. Date: Jan. 28, 2021

(54) IMAGING PANEL

(71) Applicant: Sharp Kabushiki Kaisha, Osaka (JP)

(72) Inventors: Makoto NAKAZAWA, Sakai City (JP); Rikiya TAKITA, Sakai City (JP); Fumiki NAKANO, Sakai City (JP)

(21) Appl. No.: 16/934,049

(22) Filed: Jul. 21, 2020

Related U.S. Application Data
(60) Provisional application No. 62/878,773, filed on Jul. 26, 2019.

(51) Int. Cl. H01L 27/146; H04N 5/32

(52) U.S. Cl. CPC H01L 27/14676; H01L 27/1461; H04N 5/32

(57) ABSTRACT

An imaging panel includes: a photoelectric converting element on a substrate; a first wiring layer that does not overlap the element in plan view and that is provided more adjacent to the substrate than an anode of the element; and a second wiring layer provided at an opposite side to the substrate with respect to the element. A first insulating layer that overlaps the element and the first wiring layer in plan view is provided between the wiring layers. First and second openings that penetrate the first insulating layer are provided, the wiring layers are connected in the first opening, and the anode and the second wiring layer are connected in the second opening. An electrically independent adjustment metal layer is arranged at a position that overlaps the first opening in plan view and that is more adjacent to the substrate than the first wiring layer.

### BACKGROUND

### 1. Field

The present disclosure relates to an imaging panel.

### 2. Description of the Related Art

A photoelectric conversion device disclosed in Japanese Unexamined Patent Application Publication No. 2011-114310 includes an array substrate where a plurality of pixels is formed, and a thin-film transistor (TFT) and a photodiode are provided in each pixel on the array substrate. An upper electrode of the photodiode is covered by a second passivation layer. A contact hole (hereinafter referred to as a “contact hole H1”) that penetrates the second passivation layer is formed on the upper electrode, and a bias wire and the upper electrode are connected through the contact hole H1. Also, a source electrode of the TFT is covered by a first passivation layer and the second passivation layer. A contact hole (hereinafter referred to as a “contact hole H2”) that penetrates the first and second passivation layers is formed on the source electrode, and a data line and the source electrode are connected through the contact hole H2.

Meanwhile, in the above-described photoelectric conversion device, the first and second passivation layers are constituted by the same material, and thus there are cases in which the contact holes H1 and H2 are formed at the same time by using a photolithography method. The contact hole H1 is provided on the upper electrode of the photodiode, and the contact hole H2 is provided in a layer that is lower than the upper electrode of the photodiode. Thus, the depth of photoresist at a position where the contact hole H2 is formed is larger than the depth of photoresist at a position where the contact hole H1 is formed. The amount of exposure of the photoresist for forming the contact holes H1 and H2 is set according to the larger one of the depths of the photoresist at the positions where the contact holes H1 and H2 are formed. As a result, the opening in the photoresist, the opening being formed by exposure, becomes larger in a mortar shape at the position where the contact hole H2 is formed than at the position where the contact hole H1 is formed. The film thickness of the photoresist tends to decrease, as the position where the contact hole H2 is formed gets closer to the photodiode. In this case, the photodiode becomes more susceptible to damage due to subsequent etching, which causes an increase in dark current in the photodiode.

### SUMMARY

According to an aspect of the disclosure, there is provided an imaging panel including: a substrate; a photoelectric converting element provided on the substrate; a first wiring layer that does not overlap the photoelectric converting element in plan view and that is provided more adjacent to the substrate than an anode of the photoelectric converting element; a second wiring layer provided at an opposite side to the substrate with respect to the photoelectric converting element; a first insulating layer that is provided between the first wiring layer and the second wiring layer and that overlaps the photoelectric converting element and the first wiring layer in plan view; a first opening that penetrates the first insulating layer to provide connection between the first wiring layer and the second wiring layer; a second opening that penetrates the first insulating layer to provide connection between the anode and the second wiring layer; and an adjustment metal layer that overlaps the first opening in plan view and that is provided more adjacent to the substrate than the first wiring layer. The adjustment metal layer is electrically independently provided on the substrate.

According to the above-described configuration, it is possible to provide an imaging panel in which dark current in a photodiode is less likely to be generated.

### BRIEF DESCRIPTION OF THE DRAWINGS

FIG. 1 is a schematic diagram showing a schematic configuration of an X-ray imaging device in a first embodiment;

FIG. 2 is a plan view showing a schematic configuration of the imaging panel shown in FIG. 1;

FIG. 3 is an enlarged plan view of one pixel in the imaging panel shown in FIG. 2;

FIG. 4A is a schematic sectional view of line IVA-IVA in the pixel shown in FIG. 3;

FIG. 4B is a schematic sectional view of line IVB-IVB in the pixel shown in FIG. 3;

FIG. 5A is a sectional view showing a manufacturing process of the imaging panel and showing a state in which a gate electrode and an adjustment wire are formed on a substrate;

FIG. 5B is a sectional view showing a process for forming a gate insulating film and a semiconductor active layer, a source electrode, and a drain electrode of a TFT on the gate electrode and the adjustment wire shown in FIG. 5A;

FIG. 5C is a sectional view showing a process for forming a first insulating film and its opening on the TFT shown in FIG. 5B;

FIG. 5D is a sectional view showing a process for forming a lower-layer lower electrode and a relay wire on the first insulating film shown in FIG. 5C;

FIG. 5E is a sectional view showing a process for forming a second insulating film and its opening on the lower-layer lower electrode and the relay wire shown in FIG. 5D;

FIG. 5F is a sectional view showing a process for forming an upper-layer lower electrode on the second insulating film shown in FIG. 5E;

FIG. 5G is a sectional view showing a process for forming a semiconductor layer, an upper electrode, and a third insulating film of a photodiode on the upper-layer lower electrode shown in FIG. 5F;

FIG. 5H is a sectional view showing a process for forming a fourth insulating film from above the third insulating film shown in FIG. 5G;

FIG. 5I is a sectional view showing a process for applying photoresist from above the fourth insulating film shown in FIG. 5H;

FIG. 5J is a sectional view showing a process for forming an opening in the photoresist shown in FIG. 5I;

FIG. 5K is a sectional view showing a process for forming a contact hole at a position of the opening in the photoresist shown in FIG. 5J;

FIG. 5L is a sectional view showing a process for forming a first planarization film on the fourth insulating film shown in FIG. 5K;

FIG. 5M is a sectional view showing a process for forming a bias wire and a data line on the first planarization film shown in FIG. 5L;

FIG. 5N is a sectional view showing a process for forming a fifth insulating film from above the bias wire and the data line shown in FIG. 5M;

FIG. 5O is a sectional view showing a process for forming a second planarization film on the fifth insulating film shown in FIG. 5N and forming a sixth insulating film on the second planarization film;

FIG. 6A is a sectional view showing a comparative example in which an adjustment wire is not provided in FIG. 5I and is a view for describing a height of the fourth insulating film from a surface of the photoresist;

FIG. 6B is a sectional view for describing the height of the fourth insulating film from the surface of the photoresist when compared with FIG. 6A;

FIG. 7 is a schematic sectional view of an imaging panel in a second embodiment;

FIG. 8A is a sectional view for describing a manufacturing process of the imaging panel shown in FIG. 7 and is a sectional view showing a process for forming an adjustment wire, a gate electrode, and a gate insulating film on a substrate;

FIG. 8B is a sectional view showing a process for forming an opening in the gate insulating film shown in FIG. 8A;

FIG. 8C is a sectional view showing a process for forming a semiconductor active layer, a source electrode, and a drain electrode of a TFT and a first insulating film on the gate insulating film shown in FIG. 8B;

FIG. 9 is a schematic sectional view of an imaging panel in a third embodiment;

FIG. 10A is a sectional view showing a manufacturing process of the imaging panel shown in FIG. 9 and showing a process for forming a basecoat layer on a substrate;

FIG. 10B is a sectional view showing a process for forming an opening in the basecoat layer shown in FIG. 10A;

FIG. 10C is a sectional view showing a process for forming an adjustment wire and a gate electrode on the basecoat layer shown in FIG. 10B;

FIG. 10D is a sectional view showing a process for forming a gate insulating film on an adjustment wire and a gate electrode shown in FIG. 10C;

FIG. 10E is a sectional view showing a process for forming a semiconductor active layer, a source electrode, and a drain electrode of a TFT and a first insulating film on the gate insulating film shown in FIG. 10D;

FIG. 11 is a schematic sectional view of an imaging panel in a fourth embodiment;

FIG. 12A is a sectional view for describing a manufacturing process of the imaging panel shown in FIG. 11 and is a sectional view showing a process for forming a gate insulating film, a TFT, and a first insulating film on a substrate;

FIG. 12B is a sectional view showing a process for forming a third planarization film on the first insulating film shown in FIG. 12A;

FIG. 12C is a sectional view showing a process for forming a relay wire and a lower-layer lower electrode on the third planarization film shown in FIG. 12B;

FIG. 12D is a sectional view showing a process for forming a second insulating film on the relay wire and the lower-layer lower electrode shown in FIG. 12C; and

FIG. 12E is a sectional view showing a process for forming an upper-layer lower electrode on the lower-layer lower electrode shown in FIG. 12D.

### DESCRIPTION OF THE EMBODIMENTS

Embodiments of the present disclosure will be described below in detail with reference to the accompanying drawings. In the drawings, the same or corresponding portions are denoted by the same reference numerals, and descriptions thereof are not repeated.

### First Embodiment

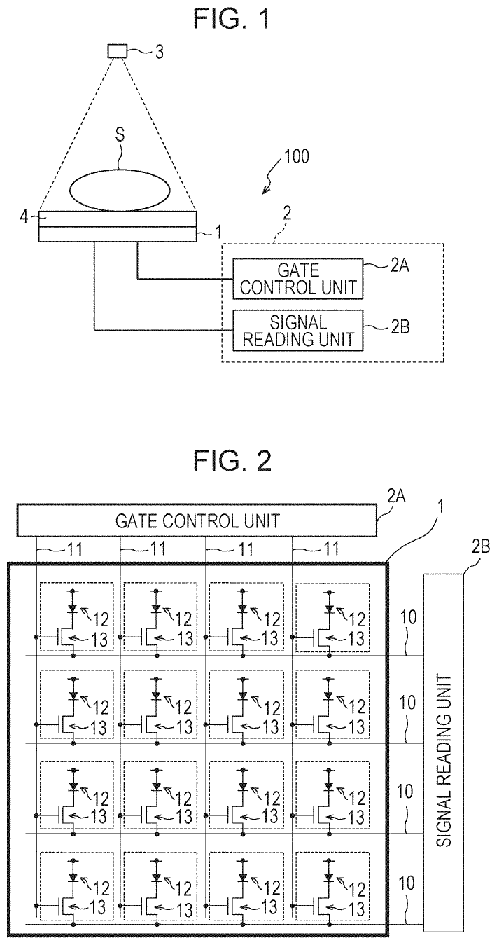

FIG. 1 is a schematic diagram showing an X-ray imaging device to which an imaging panel in the present embodiment is applied. An X-ray imaging device 100 includes an imaging panel 1, a control unit 2, an X-ray source 3, and a scintillator 4 on the imaging panel 1. The control unit 2 has a gate control unit 2A and a signal reading unit 2B. When an X-ray is radiated from the X-ray source 3, the X-ray transmitted through a subject S is converted into fluorescent light (hereinafter, “scintillation light”) by the scintillator 4. In the imaging panel 1, the scintillation light is photoelectrically converted, and electrical signals obtained by the photoelectric conversion are read out to the signal reading unit 2B under the control of the gate control unit 2A. The configuration of the imaging panel 1 will be described below in detail.

### (Configuration)

FIG. 2 is a schematic plan view showing a schematic configuration of the imaging panel 1. As shown in FIG. 2, a plurality of source wires 10 and a plurality of gate wires 11 that intersect the plurality of source wires 10 are formed in the imaging panel 1. The plurality of gate wires 11 is connected to the gate control unit 2A, and the plurality of source wires 10 is connected to the signal reading unit 2B.

The imaging panel 1 has a plurality of pixels as a light-receiving area that receives the scintillation light resulting from conversion of the X-ray transmitted through the subject S. The plurality of pixels is defined by the source wires 10 and the gate wires 11. Each pixel is provided with a TFT 13 and a photodiode 12.

The gate wires 11 are sequentially switched into selected states by the gate control unit 2A, and the TFTs 13 connected to the gate wires 11 that are in the selected states enter on states. When the TFTs 13 in the pixels enter the on states, signals corresponding to charge resulting from conversion of the scintillation light by the photodiodes 12 in the pixels are output to the signal reading unit 2B through the source wires 10.

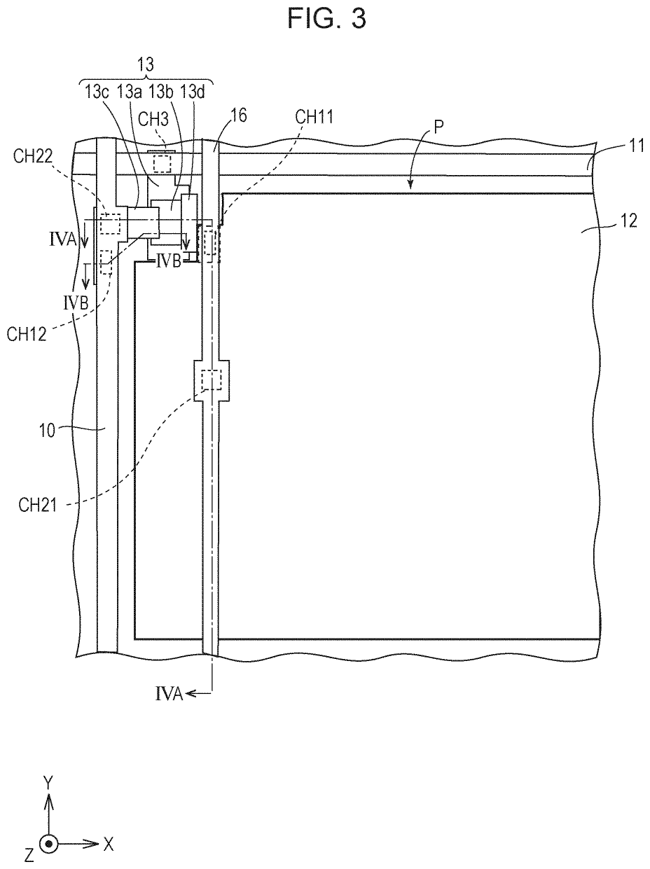

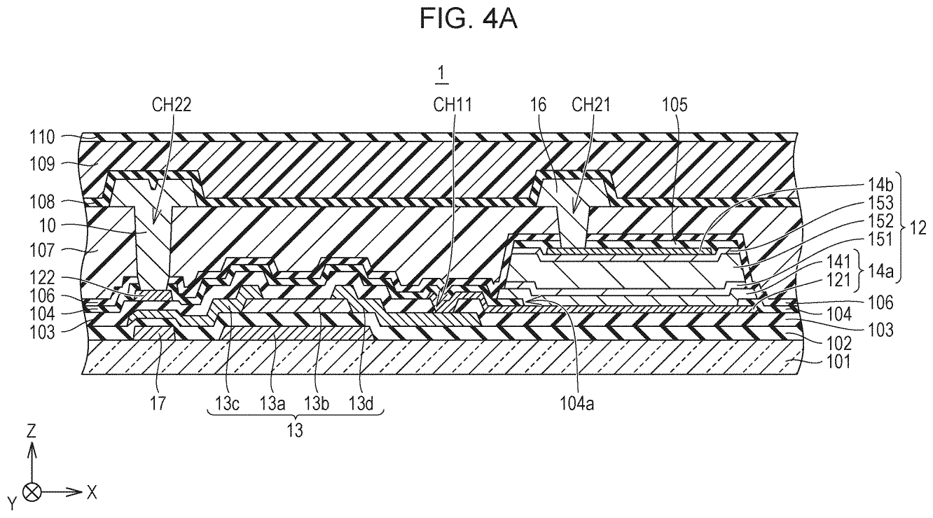

FIG. 3 is a schematic enlarged plan view of one pixel in the imaging panel 1 shown in FIG. 2. As shown in FIG. 3, the photodiode 12 and the TFT 13 are provided in a pixel P.

The TFT 13 has a gate electrode 13a, a semiconductor active layer 13b, a source electrode 13c, and a drain electrode 13d. The gate electrode 13a is connected to the gate wire 11 through a contact hole CH3. The source electrode 13c is connected to a data wire 10 through a contact hole CH22. The drain electrode 13d is connected to the photodiode 12 through a contact hole CH11.

A bias wire 16 is arranged generally in parallel to the gate wire 11 so as to overlap the photodiode 12 in plan view. The photodiode 12 is connected to the bias wire 16 through a contact hole CH21. A bias voltage is supplied to the photodiode 12 through the bias wire 16.

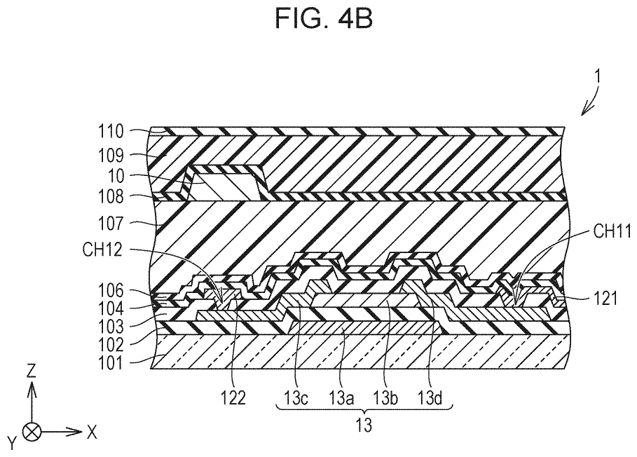

Now, a cross-sectional structure of the pixel P will be described with reference to FIGS. 4A and 4B. FIG. 4A is a schematic sectional view along line IVA-IVA in FIG. 3, and FIG. 4B is a schematic sectional view along line IVB-IVB in FIG. 3. In the description below, a Z-axis positive direction side may be referred to as “upper”, and a Z-axis negative direction side may be referred to as “lower”.

As shown in FIG. 4A, the gate electrode 13a and an adjustment metal 17 are provided on a substrate 101. In the present embodiment, the adjustment metal 17 is one example of an adjustment metal layer. The adjustment metal 17 is a wire provided for adjusting the height of an insulating layer from the substrate 101. The contact hole CH22 penetrates the insulating layer. A specific description of a function of the adjustment metal 17 is given below.

The substrate 101 has an insulation property and is constituted by, for example, a glass substrate.

The gate electrode 13a and the adjustment metal 17 have, for example, a stacked structure in which tantalum nitride (TaN) is stacked at a lower layer, and tungsten (W) is stacked at an upper layer. For example, the film thickness of the tantalum nitride (TaN) may be about 30 to 100 nm, and the film thickness of the tungsten (W) may be about 300 to 500 nm. The compositions of the gate electrode 13a and the adjustment metal 17 are not limited to the above-described compositions.

The gate electrode 13a and the adjustment metal 17 are covered by a gate insulating film 102. The gate insulating film 102 has a stacked structure in which an inorganic insulating film made of silicon nitride (SiNx) is stacked at a lower layer, and an inorganic insulating film made of silicon oxide (SiOx) is stacked at an upper layer. The film thickness of the inorganic insulating film made of silicon nitride (SiNx) may be about 325 nm, and the film thickness of the inorganic insulating film made of silicon oxide (SiOx) may be about 50 nm. The composition of the gate insulating film 102 is not limited to this composition.

The semiconductor active layer 13b, the source electrode 13c, and the drain electrode 13d are provided on the gate insulating film 102. The semiconductor active layer 13b overlaps the gate electrode 13a in plan view. The source electrode 13c and the drain electrode 13d are spaced apart from each other on the semiconductor active layer 13b and cover part of the semiconductor active layer 13b. As shown in FIG. 4A, part of the source electrode 13c overlaps the adjustment metal 17 in plan view.

The semiconductor active layer 13b is constituted by, for example, oxide semiconductor. For example, amorphous oxide semiconductor or the like that contains indium (In), gallium (Ga), and zinc (Zn) in predetermined proportions may be used for the oxide semiconductor. The film thickness of the semiconductor active layer 13b may be, for example, about 100 nm. However, the composition of the semiconductor active layer 13b is not limited to this composition.

The source electrode 13c and the drain electrode 13d have, for example, a stacked structure in which three metal films of titanium (Ti), aluminum (Al), and titanium (Ti) are stacked in order from the lower layer. The film thicknesses of these three layers may be about 50 nm, 300 nm, and 50 nm in order from the lower layer. The compositions of the source electrode 13c and the drain electrode 13d are not limited to the compositions. For example, the source electrode 13c and the drain electrode 13d may be constituted by a single layer or two or more layers.

Although not shown in FIGS. 4A and 4B, the gate wire 11 (see FIG. 3) has the same material and the same film thickness as those of the source electrode 13c and the drain electrode 13d. In a process in which the source electrode 13c and the drain electrode 13d are fabricated, the gate wire 11 is fabricated at the same time. As described above, the gate wire 11 is connected to the gate electrode 13a through the contact hole CH3 (see FIG. 3).

A first insulating film 103 is provided on the source electrode 13c and the drain electrode 13d. As shown in FIGS. 4A and 4B, the first insulating film 103 has the contact hole CH11 at a position that overlaps the drain electrode 13d in plan view. Also, as shown in FIG. 4B, the first insulating film 103 has a contact hole CH12 at a position that overlaps the source electrode 13c in plan view. Surfaces of the source electrode 13c and the semiconductor active layer 13b and part of a surface of the drain electrode 13d are covered by the first insulating film 103.

The first insulating film 103 is constituted by, for example, an inorganic insulating film made of silicon oxide (SiO₂). The film thickness of the first insulating film 103 may be, for example, about 500 nm. The composition of the first insulating film 103 is not limited to this composition. For example, the first insulating film 103 may have a stacked structure in which an inorganic insulating film made of silicon oxide and an inorganic insulating film made of silicon nitride are stacked.

A lower-layer lower electrode 121 and a relay wire 122 are provided on the first insulating film 103. The relay wire 122 is one example of a first wiring layer. The lower-layer lower electrode 121 is connected to the drain electrode 13d through the contact hole CH11. As shown in FIGS. 4A and 4B, the relay wire 122 is provided at a position that overlaps the adjustment metal 17 in plan view. In FIG. 4B, the relay wire 122 is connected to the source electrode 13c through the contact hole CH12.

The lower-layer lower electrode 121 and the relay wire 122 have, for example, a stacked structure in which three metal films of titanium (Ti), aluminum (Al), and titanium (Ti) are stacked in order from the lower layer. The film thicknesses of these metal films are about 50 nm, about 300 nm, and about 50 nm in order from the lower layer. The compositions of the lower-layer lower electrode 121 and the relay wire 122 are not limited to the compositions.

A second insulating film 104 is provided on the lower-layer lower electrode 121 and the relay wire 122. The second insulating film 104 has an opening 104a at a position that does not overlap the TFT 13 in plan view and that overlaps the lower-layer lower electrode 121 in plan view. The second insulating film 104 covers an entire surface of the relay wire 122 and part of the lower-layer lower electrode 121.

The second insulating film 104 is constituted by, for example, an inorganic insulating film made of silicon oxide (SiO₂). The film thickness of the second insulating film 104 may be about 400 nm. The composition of the second insulating film 104 is not limited to this composition.

An upper-layer lower electrode 141 is provided on the second insulating film 104. The upper-layer lower electrode 141 is provided at a position that does not overlap the TFT 13 in plan view and that overlaps the opening 104a in plan view. The upper-layer lower electrode 141 is connected to the lower-layer lower electrode 121 through the opening 104a. In the present embodiment, the lower-layer lower electrode 121 and the upper-layer lower electrode 141 constitute a lower electrode (cathode) 14a of the photodiode 12.

The upper-layer lower electrode 141 is constituted by, for example, a metal film made of titanium (Ti). The film thickness of the upper-layer lower electrode 141 may be about 100 nm. However, the composition of the upper-layer lower electrode 141 is not limited to this composition.

An n-type amorphous semiconductor layer 151, an intrinsic amorphous semiconductor layer 152, and a p-type amorphous semiconductor layer 153 are stacked on the upper-layer lower electrode 141 in that order as a photoelectric conversion layer of the photodiode 12.

The n-type amorphous semiconductor layer 151 is made of amorphous silicon in which an n-type impurity (for example, phosphorous) is doped. The intrinsic amorphous semiconductor layer 152 is made of intrinsic amorphous silicon. The p-type amorphous semiconductor layer 153 is made of amorphous silicon in which a p-type impurity (for example, boron) is doped. In this example, the film thickness of the n-type amorphous semiconductor layer 151 may be about 10 to 100 nm, and the film thickness of the intrinsic amorphous semiconductor layer 152 may be about 200 to 2000 nm. The film thickness of the p-type amorphous semiconductor layer 153 may be about 10 to 50 nm. However, the dopants and the film thicknesses of the n-type amorphous semiconductor layer 151, the intrinsic amorphous semiconductor layer 152, and the p-type amorphous semiconductor layer 153 are not limited to those described above.

An upper electrode (anode) 14b of the photodiode 12 is provided on the p-type amorphous semiconductor layer 153. As shown in FIG. 4A, the width of the upper electrode 14b in an X-axis direction is smaller than that of the p-type amorphous semiconductor layer 153.

The upper electrode 14b is constituted by, for example, a transparent conductive film made of ITO (Indium Tin Oxide) or IZO (Indium Zn Oxide). The film thickness of the upper electrode 14b may be about 100 nm. However, the material and the film thickness of the upper electrode 14b are not limited to those described above.

A third insulating film 105 is provided on the upper electrode 14b and the p-type amorphous semiconductor layer 153. Also, a fourth insulating film 106 is provided on the third insulating film 105. The third insulating film 105 is provided only at a position that overlaps the photodiode 12 in plan view. The fourth insulating film 106 covers a side surface of the photodiode 12.

As shown in FIG. 4A, the contact hole CH21 that penetrates the third insulating film 105 and the fourth insulating film 106 is provided at a position that overlaps the upper electrode 14b in plan view. Also, the contact hole CH22 that penetrates the third insulating film 105 and the fourth insulating film 106 is provided at a position that overlaps the relay wire 122 in plan view.

The third insulating film 105 and the fourth insulating film 106 are constituted by, for example, inorganic insulating films made of silicon nitride (SiN). In the present embodiment, the fourth insulating film 106 is one example of a first insulating layer or an insulating layer. The film thickness of the third insulating film 105 may be about 50 nm, and the film thickness of the fourth insulating film 106 may be about 250 nm. However, the compositions of the third insulating film 105 and the fourth insulating film 106 are not limited to the compositions.

A first planarization film 107 is provided on the fourth insulating film 106 and at a position that does not overlap the contact holes CH22 and CH21 in plan view. That is, the first planarization film 107 is spaced apart from another at the contact holes CH22 and CH21.

The first planarization film 107 is constituted by, for example, an organic transparent resin made of an acryl-based resin or a siloxane-based resin. The film thickness of the first planarization film 107 may be about 2.5 μm. However, the material and the film thickness of the first planarization film 107 are not limited to those described above.

The bias wire 16 and the data wire 10 are provided on the first planarization film 107. In the present embodiment, the bias wire 16 and the data wire 10 are one example of a second wiring layer. The bias wire 16 overlaps the upper electrode 14b in plan view and is connected to the upper electrode 14b through the contact hole CH21. The data wire 10 overlaps the relay wire 122 in plan view and is connected to the relay wire 122 through the contact hole CH22. As described above, in FIG. 4B, the relay wire 122 is connected to the source electrode 13c through the contact hole CH22. The data wire 10 is connected to the source electrode 13c through the relay wire 122.

The bias wire 16 is connected to the control unit 2 (see FIG. 1) to apply a bias voltage, input from the control unit 2, to the photodiode 12. The bias wire 16 and the data wire 10 have, for example, a stacked structure in which a metal film of titanium (Ti), a metal film of aluminum (Al), and a metal film of titanium (Ti) are stacked in order from the lower layer. The film thicknesses of the metal films may be about 50 nm, about 300 nm, and about 50 nm in order from the lower layer. However, the materials and the film thicknesses of the bias wire 16 and the data wire 10 are not limited to those described above.

A fifth insulating film 108 is provided on the bias wire 16 and the data wire 10. Surfaces of the bias wire 16 and the data wire 10 are covered by the fifth insulating film 108. The fifth insulating film 108 is constituted by, for example, an inorganic insulating film made of silicon nitride (SiNx). The film thickness of the fifth insulating film 108 may be about 300 nm. However, the material and the film thickness of the fifth insulating film 108 are not limited to those described above.

A second planarization film 109 is provided on the fifth insulating film 108. The second planarization film 109 is constituted by, for example, an organic transparent resin made of an acryl-based resin or a siloxane-based resin. The film thickness of the second planarization film 109 may be, for example, about 3.0 μm. However, the material and the film thickness of the second planarization film 109 are not limited to those described above.

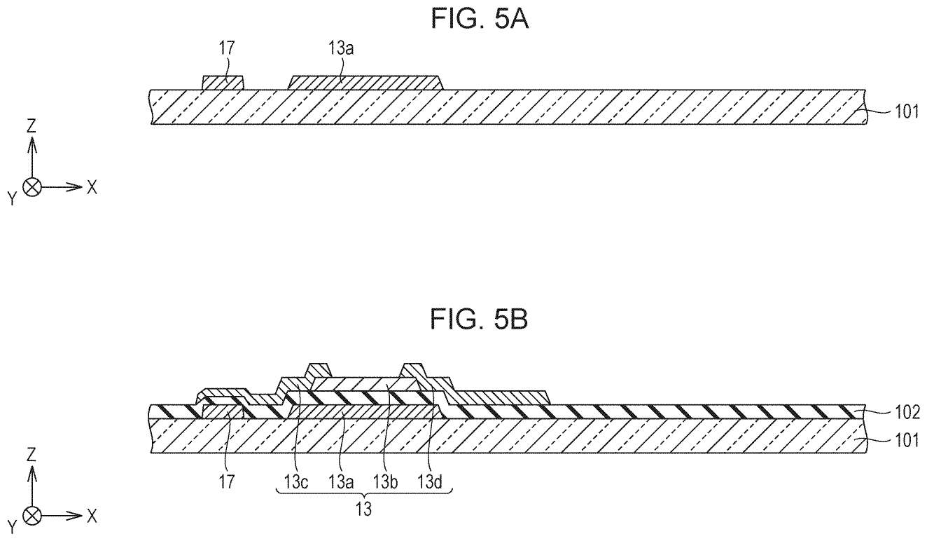

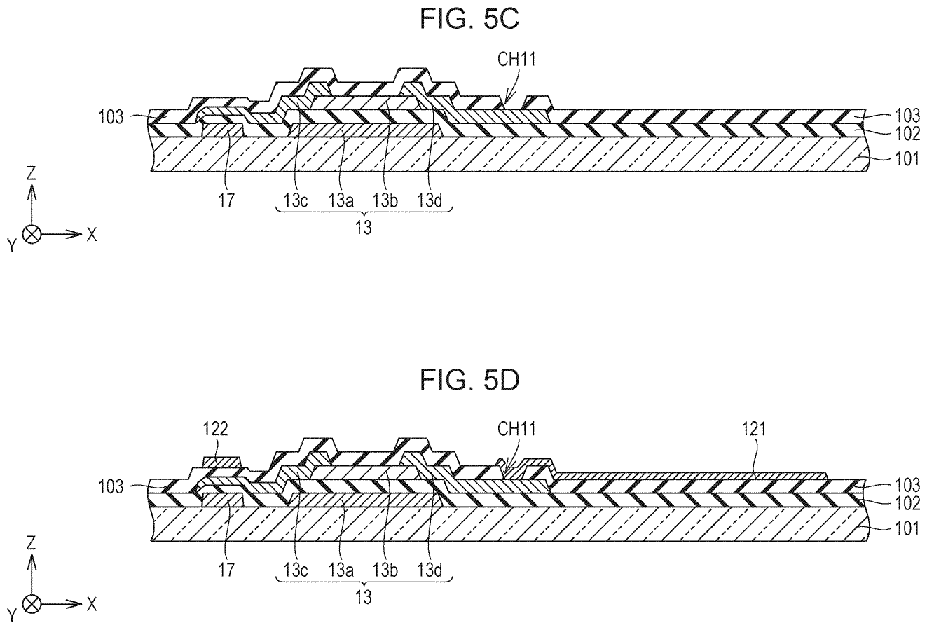

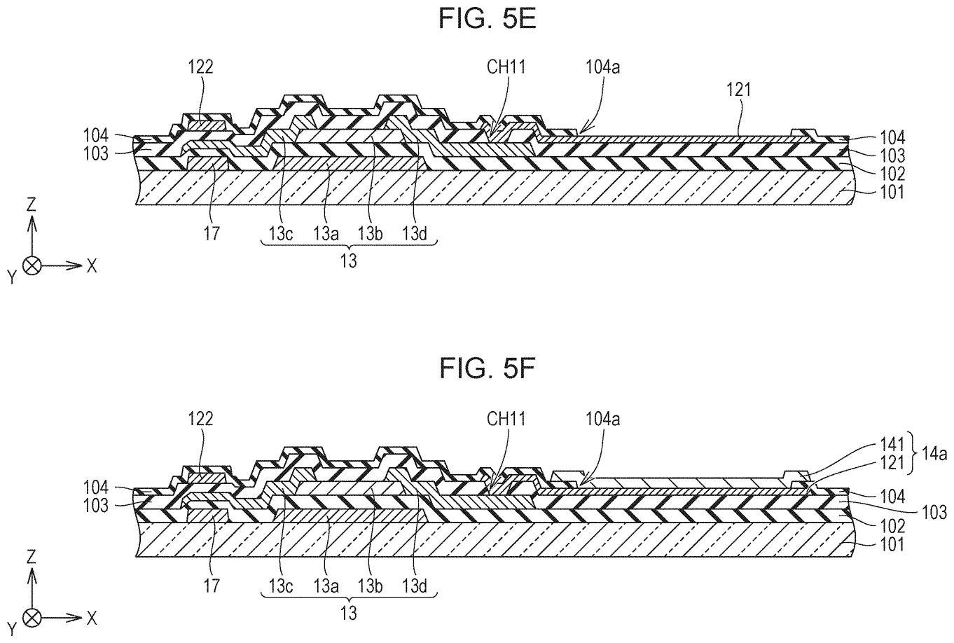

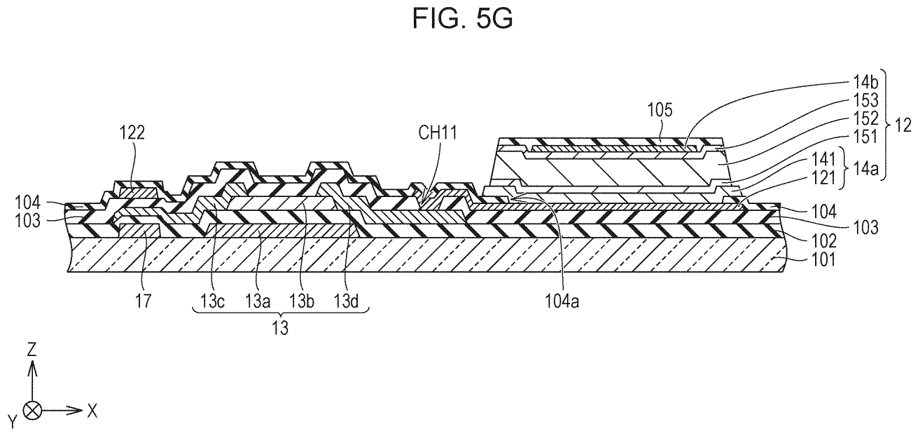

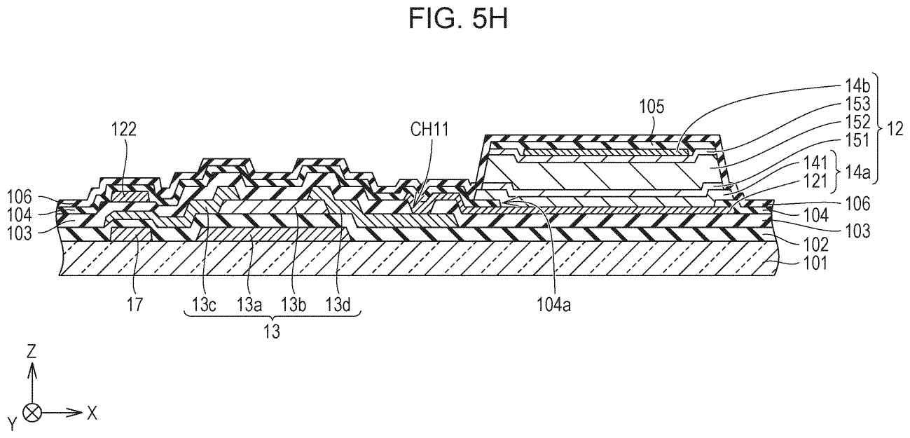

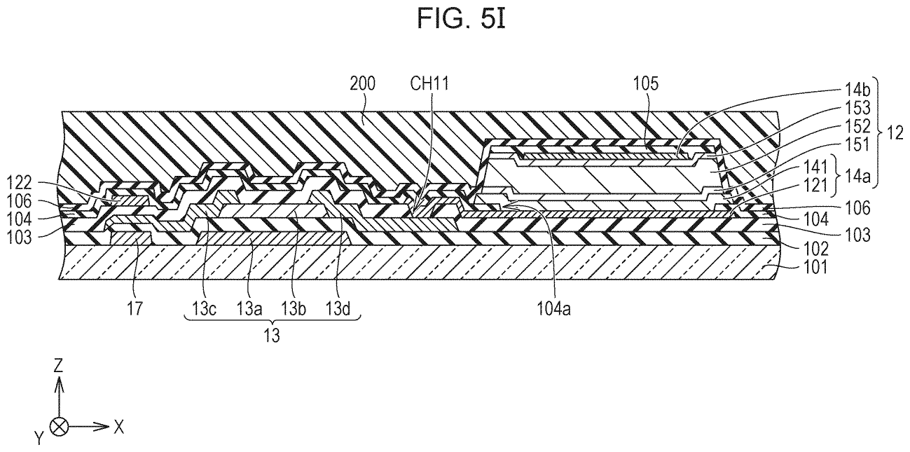

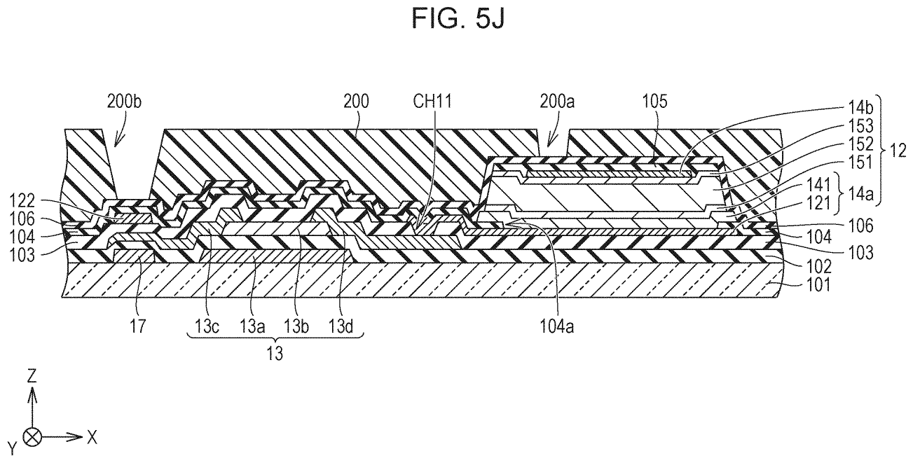

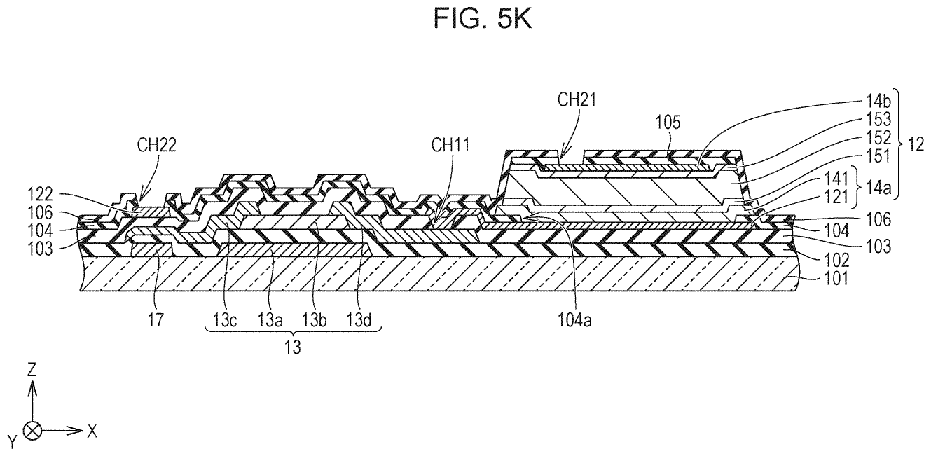

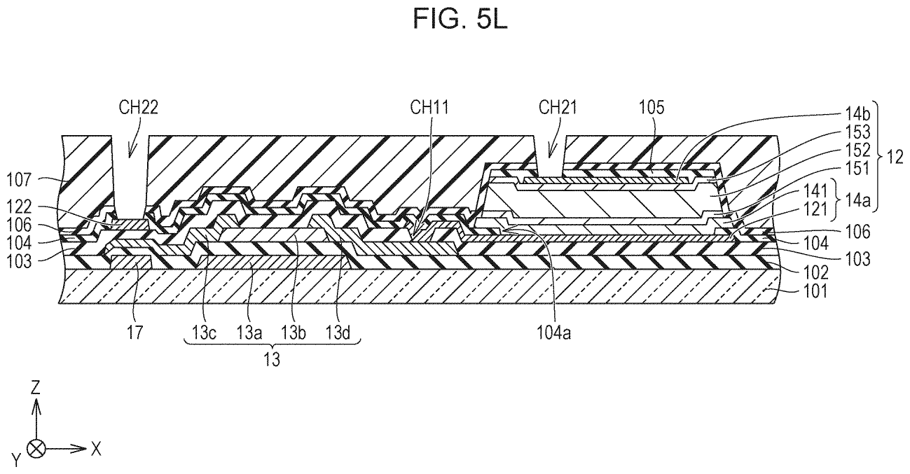

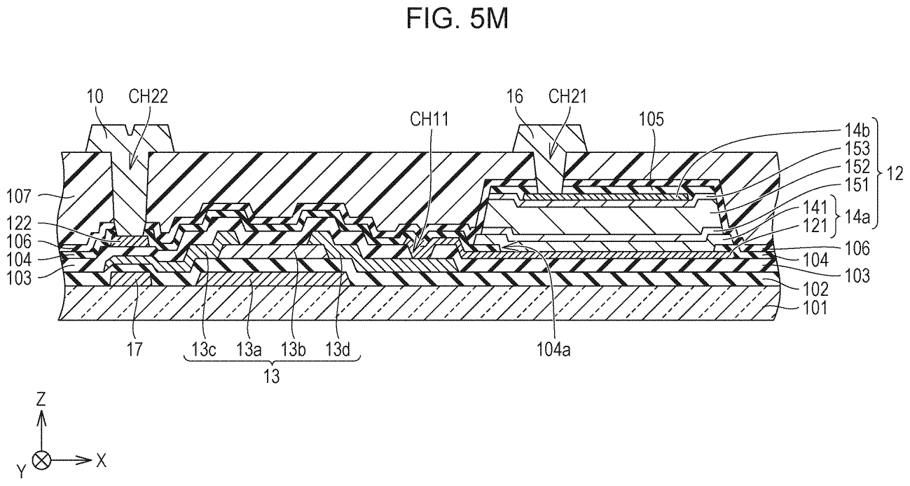

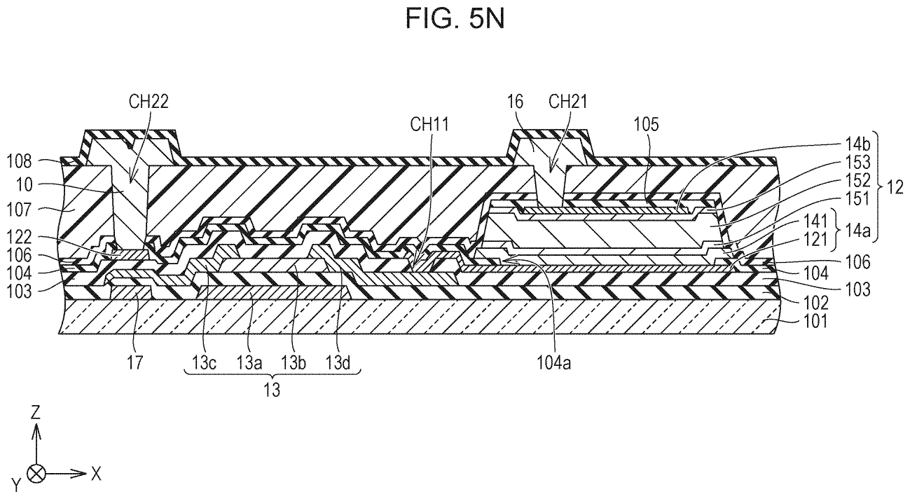

Next, a description will be given of a manufacturing method for the imaging panel 1. FIGS. 5A to 5O are sectional views for describing a manufacturing process for the imaging panel 1. The manufacturing process will be described below with reference to FIGS. 5A to 5O.

First, for example, using a sputtering method, a metal film made of tantalum nitride (TaN) and a metal film made of tungsten (W) are formed on the substrate 101, respectively, at a lower layer and an upper layer in order. Thereafter, a photolithography method and dry etching are performed to pattern the stacked metal films. As a result, the gate electrode 13a and the adjustment metal 17 that are arranged apart from each other are formed on the substrate 101 (see FIG. 5A).

Next, for example, using a CVD (Chemical Vapor Deposition) method, the gate insulating film 102 made of silicon oxide (SiO₂) is formed from above the gate electrode 13a and the adjustment metal 17. Subsequently, for example, using a sputtering method, a film of oxide semiconductor that contains indium (In), gallium (Ga), zinc (Zn), and oxygen (O₂) in predetermined proportions is formed on the gate insulating film 102. Thereafter, a photolithography method and dry etching are performed to pattern the oxide semiconductor. Subsequently, for example, using a sputtering method, a metal film of titanium (Ti), a metal film of aluminum (Al), and a metal film of titanium (Ti) are formed in order. Then, a photolithography method and dry etching are performed to pattern the stacked metal films. As a result, the semiconductor active layer 13b that overlaps the gate electrode 13a in plan view is formed on the gate insulating film 102, and the source electrode 13c and the drain electrode 13d that are arranged apart from each other on the semiconductor active layer 13b are formed (see FIG. 5B). That is, in this process, the TFT 13 is formed. The source electrode 13c formed in the process is arranged so as to overlap the adjustment metal 17 in plan view.

Subsequently, for example, using a CVD method, an inorganic insulating film made of silicon oxide (SiO₂) is formed from above the source electrode 13c and the drain electrode 13d. Then, a photolithography method and dry etching are performed to pattern the inorganic insulating film. As a result, the first insulating film 103 having the contact hole CH11 at a position that overlaps the drain electrode 13d in plan view is formed (see FIG. 5C).

Thereafter, for example, using a sputtering method, a metal film of titanium (Ti), a metal film of aluminum (Al), and a metal film of titanium (Ti) are formed on the first insulating film 103 in order. Then, a photolithography method and dry etching are performed to pattern the stacked metal films. As a result, the relay wire 122 that overlaps the adjustment metal 17 in plan view and the lower-layer lower electrode 121 that is connected to the drain electrode 13d through the contact hole CH11 are formed (see FIG. 5D).

For example, using a CVD method, an inorganic insulating film made of silicon oxide (SiO₂) is formed from above the lower-layer lower electrode 121, and then a photolithography method and dry etching are performed to pattern the inorganic insulating film. As a result, the second insulating film 104 having the opening 104a at a position that does not overlap the TFT 13 in plan view is formed on the lower-layer lower electrode 121 (see FIG. 5E).

Thereafter, for example, using a sputtering method, a metal film made of titanium (Ti) is formed on the second insulating film 104. Then, a photolithography method and dry etching are performed to pattern the metal film. As a result, the upper-layer lower electrode 141 connected to the lower-layer lower electrode 121 is formed in the opening 104a, so that the lower electrode 14a constituted by the lower-layer lower electrode 121 and the upper-layer lower electrode 141 is formed (see FIG. 5F).

Next, the photoelectric conversion layer and the upper electrode 14b of the photodiode 12 and the third insulating film 105 are formed in order (see FIG. 5G). Specifically, for example, using a CVD method, the n-type amorphous semiconductor layer 151, the intrinsic amorphous semiconductor layer 152, and the p-type amorphous semiconductor layer 153, which serve as a photoelectric conversion layer, are formed in order from above the upper-layer lower electrode 141. Thereafter, for example, using a sputtering method, a transparent conductive film made of ITO is formed from above the p-type amorphous semiconductor layer 153. Then, a photolithography method and dry etching are performed to pattern the transparent conductive film. As a result, the upper electrode 14b is formed on the p-type amorphous semiconductor layer 153. Subsequently, a photolithography method and dry etching are performed on the photoelectric conversion layer to pattern the photoelectric conversion layer. As a result, the photoelectric conversion layer (151 to 153) whose width in the X-axis direction is smaller than that of the lower electrode 14a is formed to form the photodiode 12.

Thereafter, for example, using a CVD method, an inorganic insulating film made of silicon nitride (SiNx) is formed from above the upper electrode 14b so as to cover a surface of the photodiode 12. Then, for example, a photolithography method and dry etching are performed to pattern the inorganic insulating film. As a result, the third insulating film 105 that covers a surface of the upper electrode 14b and a top of the p-type amorphous semiconductor layer 153 is formed.

Next, for example, using a CVD method, the fourth insulating film 106 made of silicon nitride (SiNx) is formed so as to cover the surface of the photodiode 12 (see FIG. 5H).

Subsequently, a photoresist 200 is applied from above the fourth insulating film 106 (see FIG. 5I). Thereafter, the photoresist 200 is exposed and developed. As a result, the photoresist 200 at a position that overlaps the upper electrode 14b in plan view and at a position that overlaps the relay wire 122 in plan view are removed to form openings 200a and 200b (see FIG. 5J). The photoresist 200 formed as described above is used as a pattern mask for forming the contact holes CH21 and CH22.

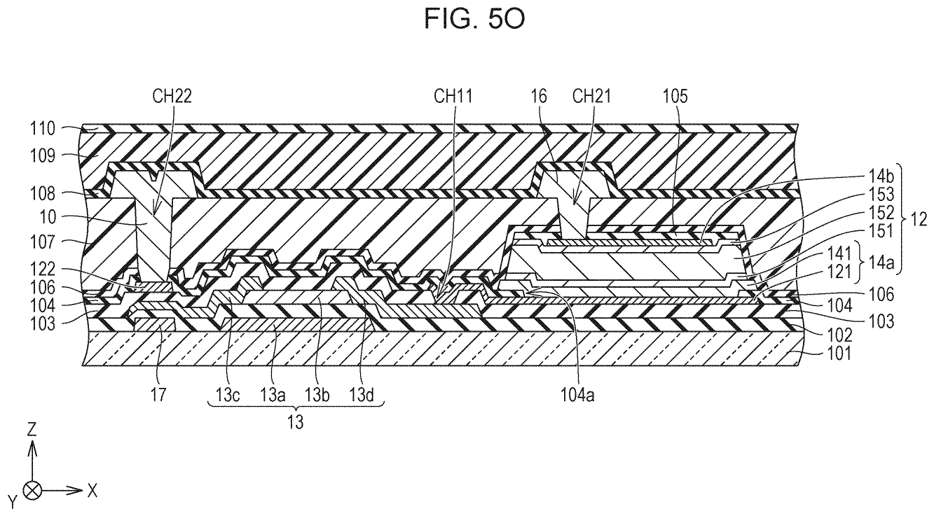

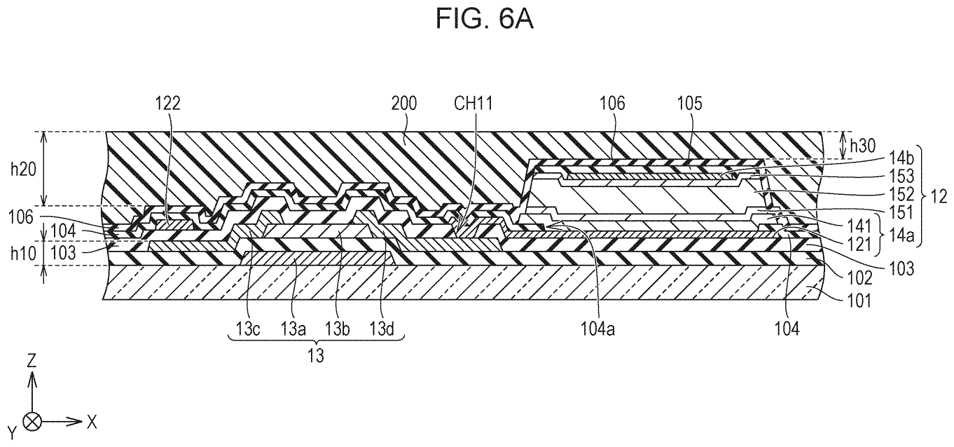

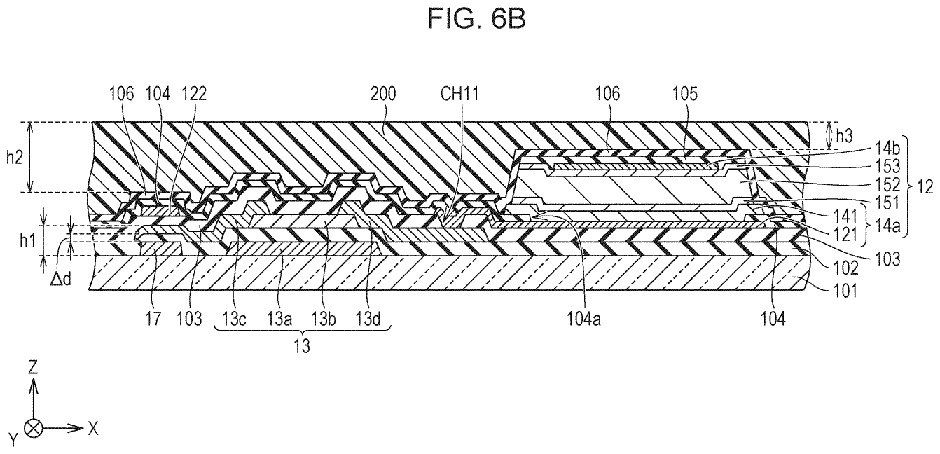

Now, FIG. 6A shows a cross-sectional structure when the adjustment metal 17 is not provided. Also, for comparison with FIG. 6A, FIG. 6B shows the same structure as in FIG. 5I. The structure in FIG. 6A is the same as the structure in FIG. 5I, except that the adjustment metal 17 is not provided. The film thickness of the photoresist 200 over the photodiode 12 in FIG. 6A is assumed to be equal to the corresponding film thickness in FIG. 5I.

In FIGS. 6A and 6B, heights h10 and h1 from a surface of the substrate 101 to a surface of the source electrode 13c have a relationship h10<h1. When the adjustment metal 17 is not provided, the gate insulating film 102 under the source electrode 13c is generally planar. However, when the adjustment metal 17 is provided, the gate insulating film 102 protrudes upward on the adjustment metal 17 by an amount corresponding to Δd. As a result, in the case of FIG. 6B, the height h1 from the surface of the substrate 101 to the surface of the source electrode 13c is about Δd larger than the height h10 in the case of FIG. 6A.

In FIGS. 6A and 6B, the second insulating film 104 and the fourth insulating film 106 are provided over the source electrode 13c, and the film thicknesses of these insulating films over the source electrode 13c in FIG. 6A and the film thicknesses of these insulating films over the source electrode 13c in FIG. 6B are equal to each other. Thus, when the adjustment metal 17 is provided, a height h2 from the fourth insulating film 106 at a position that overlaps the relay wire 122 in plan view to the surface of the photoresist 200 is about Δd smaller than a height h20 when the adjustment metal 17 is not provided. That is, since the adjustment metal 17 is provided, the positions of the individual layers over the adjustment metal 17 become higher than those in FIG. 6A.

In FIGS. 6A and 6B, heights h30 and h3 from an upper surface of the fourth insulating film 106 on the photodiode 12 to the surface of the photoresist 200 are generally equal to each other. Also, the heights h30 and h3 are smaller than the heights h20 and h2. Thus, the amount of exposure of the photoresist 200 is adjusted according to a larger one of the depths from the surface of the photoresist 200 to the fourth insulating film 106. Accordingly, in this case, the amount of exposure of the photoresist 200 in the configuration (FIG. 6B) in which the adjustment metal 17 is provided is smaller than in the configuration (FIG. 6A) in which the adjustment metal 17 is not provided.

Referring back to FIG. 5J, a description of the process will be continuously given. After the openings 200a and 200b in the photoresist 200 are formed, dry etching is performed to remove the photoresist 200. As a result, the contact hole CH21 that penetrates the third insulating film 105 and the fourth insulating film 106 at the opening 200a is formed, and also the contact hole CH22 that penetrates the second insulating film 104 and the fourth insulating film 106 at the opening 200b are formed (see FIG. 5K).

As described above, the positions of the surfaces of the layers provided over the adjustment metal 17 are higher by an amount corresponding to the provision of the adjustment metal 17. Thus, the depth of the opening 200b in the photoresist 200 becomes smaller than in the case in which the adjustment metal 17 is not provided, and the amount of exposure is reduced. As a result, the film thickness of the photoresist 200 in the vicinity of the side surface of the photodiode 12 is less likely to be reduced, and thus the photodiode 12 is less susceptible to damage due to etching.

After the process in FIG. 5K, for example, a slit coating method is used to form a planarization film made of a photosensitive acryl-based resin, and then a photolithography method is used to remove the planarization film at positions that overlap the contact holes CH21 and CH22 in plan view. As a result, the first planarization film 107 is formed on the fourth insulating film 106 (see FIG. 5L).

Subsequently, for example, a sputtering method is used to form a metal film of titanium (Ti), a metal film of aluminum (Al), and a metal film of titanium (Ti) in order, and then a photolithography method and dry etching are performed. As a result, the bias wire 16 connected to the upper electrode 14b through the contact hole CH21 is formed on the first planarization film 107, and also the data wire 10 connected to the relay wire 122 through the contact hole CH22 is formed on the first planarization film 107 (see FIG. 5M).

Thereafter, for example, using a CVD method, the fifth insulating film 108 made of silicon nitride (SiNx) is formed from above the bias wire 16 and the data wire 10 (see FIG. 5N).

Then, for example, using a slit coating method, the second planarization film 109 made of a photosensitive acryl-based resin is formed on the fifth insulating film 108, and subsequently, for example, using a CVD method, a sixth insulating film 110 made of silicon nitride (SiNx) is formed on the second planarization film 109 (see FIG. 5O). As a result, the imaging panel 1 is fabricated.

### (Operation of X-Ray Imaging Device 100)

Now, a description will be given of the operation of the X-ray imaging device 100 shown in FIG. 1. First, an X-ray is radiated from the X-ray source 3. At this point in time, the control unit 2 applies a predetermined voltage (a bias voltage) to the bias wires 16 (see FIG. 3 and so on). The X-ray radiated from the X-ray source 3 is transmitted through the subject S and is incident on the scintillator 4. The X-ray that is incident on the scintillator 4 is converted into fluorescent light (scintillation light), and the scintillation light is incident on an active matrix substrate 1. When the scintillation light is incident on the photodiode 12 provided in the individual pixels in the active matrix substrate 1, the photodiode 12 converts the scintillation light into charge corresponding to the amount of the light. In response to a gate voltage (a positive voltage) output from the gate control unit 2A through the gate wires 11, the TFTs 13 (see FIG. 3 and so on) in the pixels enter an on state. Signals corresponding to the charge converted by the photodiodes 12 in the individual pixels are read out to the signal reading unit 2B (see FIG. 2 and so on) through the source wires 10 for the pixels, when the TFTs 13 in the pixels are in the on state. Then, the control unit 2 generates an X-ray image corresponding to the read signals.

### Second Embodiment

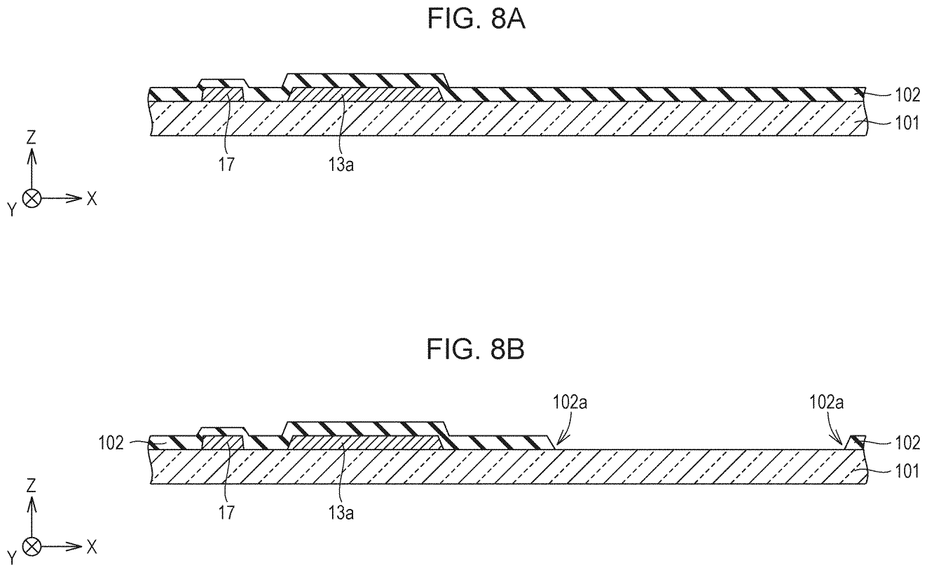

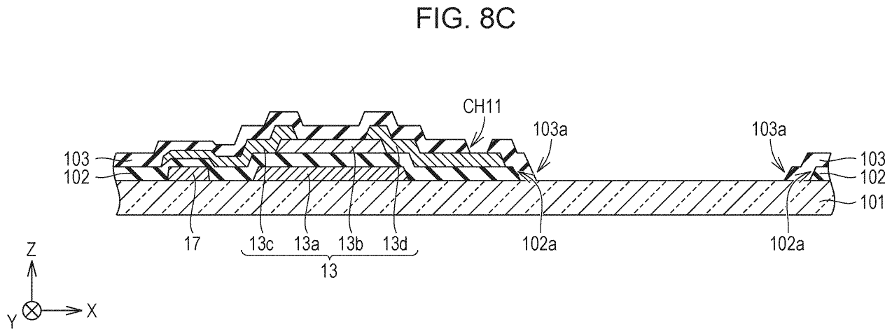

FIGS. 8A to 8C are schematic sectional views of an imaging panel in the present embodiment. In FIGS. 8A to 8C, constituent elements that are the same as those in the first embodiment are denoted by the same reference numerals as those in the first embodiment. Constituent elements that differ from those in the first embodiment will be described below.

In an imaging panel 1A, a gate insulating film 102 and a first insulating film 103 provided under a photodiode 12 have an opening 102a and an opening 103a, respectively. That is, the imaging panel 1A differs from the first embodiment (see FIG. 4A and so on) in that the photodiode 12 does not overlap the gate insulating film 102 and the first insulating film 103. In the present embodiment, the gate insulating film 102 is one example of a second insulating layer. Hence, the height of a fourth insulating film 106 over the photodiode 12 is smaller than the height of the fourth insulating film 106 over the photodiode 12 in the first embodiment (see FIG. 4A and so on). That is, the difference between the height of the fourth insulating film 106 over the photodiode 12 and the height of the fourth insulating film 106 over the relay wire 122 are smaller than in the first embodiment. Hence, a photoresist 200 (see FIG. 5L and so on) that is applied in order to form contact holes CH21 and CH22 can be generally made thinner than in the first embodiment, and the amount of exposure of the photoresist 200 can be made smaller than in the first embodiment. As a result, the photoresist 200 in the vicinity of the side surface of the photodiode 12 is also less likely to be thinned by exposure, and the photodiode 12 is less susceptible to damage due to etching.

The imaging panel 1A may be fabricated by a method below. First, the same process as in FIG. 5A in the first embodiment is performed to form an adjustment metal 17 and a gate electrode 13a on a substrate 101, and then the gate insulating film 102 is formed from above the adjustment metal 17 and the gate electrode 13a (see FIG. 8A).

Subsequently, a photolithography method and dry etching are performed to pattern the gate insulating film 102. As a result, the opening 102a in the gate insulating film 102 is formed at a position that does not overlap the gate electrode 13a and the adjustment metal 17 in plan view (see FIG. 8B).

Next, the same process as in FIG. 5B in the first embodiment is performed to form a semiconductor active layer 13b, a source electrode 13c, and a drain electrode 13d on the gate insulating film 102. Then, the same process as in FIG. 5C is performed to form the first insulating film 103 from above the source electrode 13c and the drain electrode 13d, and then a photolithography method and dry etching are performed to pattern the first insulating film 103. As a result, a contact hole CH11 is formed at a position that overlaps the drain electrode 13d in plan view, and also the opening 103a in the first insulating film 103 is formed inside the opening 102a in the gate insulating film 102 (see FIG. 8C).

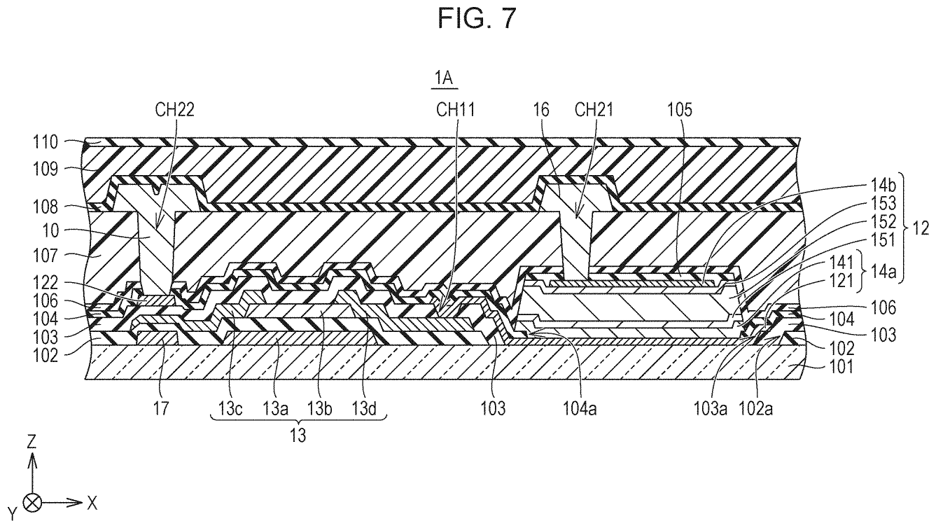

Thereafter, the same processes as in FIGS. 5D to 5O in the first embodiment are performed to thereby fabricate the imaging panel 1A (see FIG. 7).

### Third Embodiment

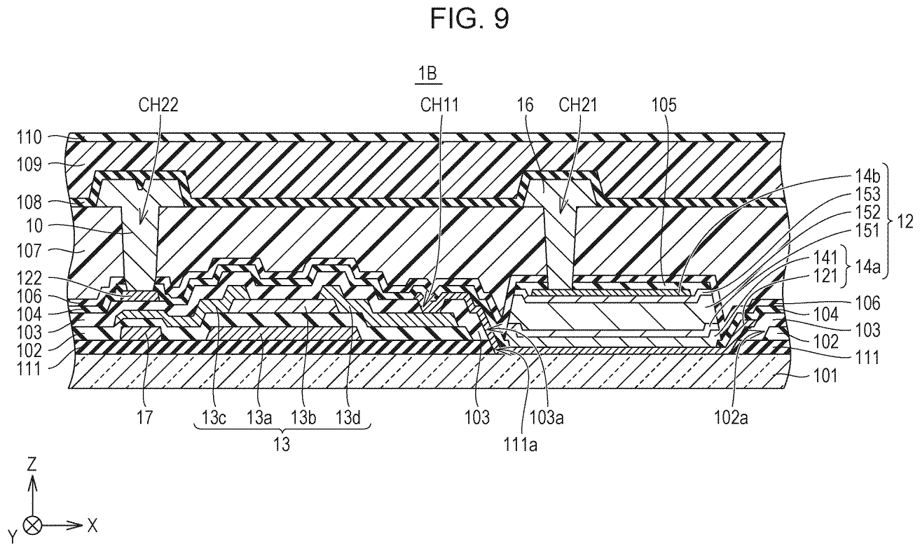

FIG. 9 is a schematic sectional view of an imaging panel according to the present embodiment. In FIG. 9, constituent elements that are the same as those in the second embodiment are denoted by the same reference numerals as those in the second embodiment. Constituent elements that differ from those in the second embodiment will be described below.

As shown in FIG. 9, an imaging panel 1B in the present embodiment differs from the imaging panel 1A (see FIG. 7) in the second embodiment in that a basecoat layer 111 is provided on a substrate 101. The basecoat layer 111 has an opening 111a at a position that overlaps a photodiode 12 in plan view. In the present embodiment, the basecoat layer 111 is one example of a third insulating layer. The basecoat layer 111 is constituted by, for example, an inorganic insulating film made of silicon oxide (SiO₂), and the film thickness thereof is about 250 nm.

The position of an end portion of the opening 111a in the basecoat layer 111 protrudes compared with an end portion of an opening 102a in a gate insulating film 102, and the opening width of the opening 111a in the basecoat layer 111 is smaller than the opening width of the opening 102a in the gate insulating film 102.

The opening width of an opening 103a in a first insulating film 103 is equal to the opening width of the opening 111a in the basecoat layer 111, and the opening 103a overlaps the opening 111a in plan view.

The basecoat layer 111 is provided below the adjustment metal 17, and the basecoat layer 111 is not provided under the photodiode 12. Thus, the difference between the height of a fourth insulating film 106 over the photodiode 12 and the height of the fourth insulating film 106 over the relay wire 122 further decreases by an amount corresponding to the film thickness of the basecoat layer 111 than in the second embodiment. Hence, the film thickness of a photoresist 200 (see FIG. 5L and so on) can be generally made thinner than in the second embodiment, and the amount of exposure of the photoresist 200 can be made smaller than in the second embodiment. As a result, the film thickness of the photoresist 200 in the vicinity of the side surface of the photodiode 12 is less likely to be reduced by exposure, and the photodiode 12 is less susceptible to damage due to etching than in the second embodiment.

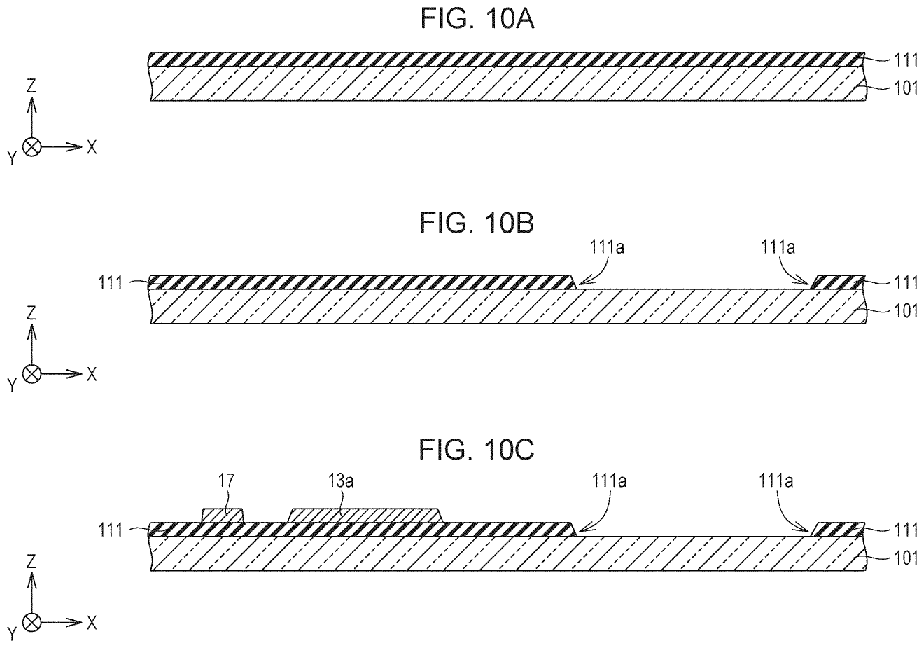

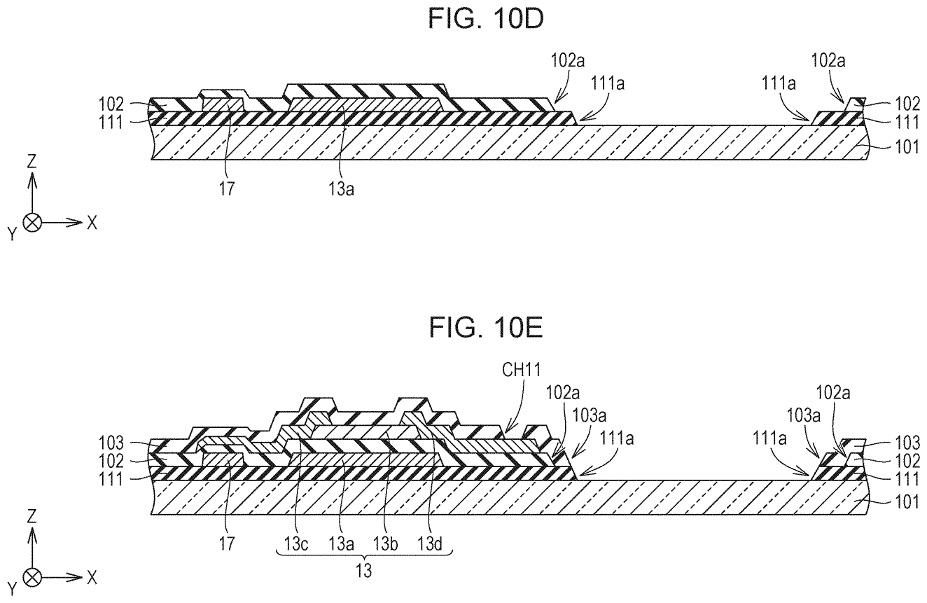

The imaging panel 1B may be fabricated by a method below. First, for example, using a CVD method, the basecoat layer 111 made of silicon nitride (SiNx) is formed on the substrate 101 (see FIG. 10A). Thereafter, a photolithography method and dry etching are performed to pattern the basecoat layer 111. As a result, the opening 111a in the basecoat layer 111 is formed (see FIG. 10B).

Subsequently, the same process as in FIG. 5A in the first embodiment is performed to form the adjustment metal 17 and the gate electrode 13a on the substrate 101 (see FIG. 10C), and the gate insulating film 102 is formed on the adjustment metal 17 and the gate electrode 13a (see FIG. 10D). As a result, the opening 102a in the gate insulating film 102 is formed on the basecoat layer 111.

Next, the same process as in FIG. 5B in the first embodiment is performed to form a semiconductor active layer 13b, a source electrode 13c, and a drain electrode 13d on the gate insulating film 102. Then, the same process as in FIG. 5C is performed to form the first insulating film 103 from above the source electrode 13c and the drain electrode 13d, and then a photolithography method and dry etching are performed to pattern the first insulating film 103. As a result, the contact hole CH11 is formed at a position that overlaps the drain electrode 13d in plan view, and also the opening 103a in the first insulating film 103 is formed inside the opening 102a in the gate insulating film 102 (see FIG. 10E).

Thereafter, the same processes as in FIGS. 5D to 5O in the first embodiment are performed to thereby fabricate the imaging panel 1B (see FIG. 9).

### Fourth Embodiment

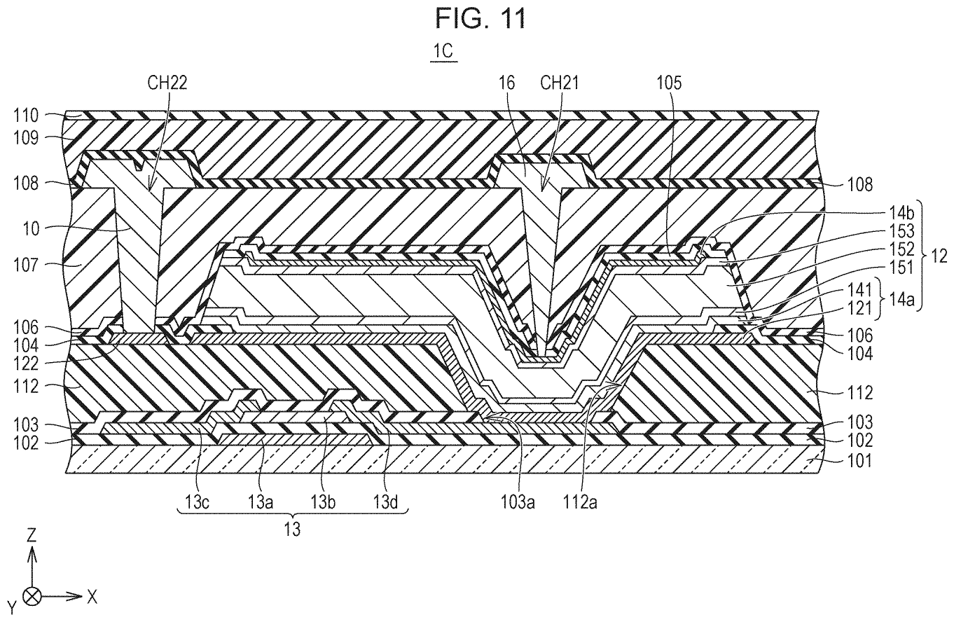

FIG. 11 is a schematic sectional view of an imaging panel in the present embodiment. In FIG. 11, constituent elements that are the same as those in the second embodiment are denoted by the same reference numerals as those in the second embodiment. Constituent elements that differ from those in the second embodiment will be described below.

An imaging panel 1C differs from the second embodiment in that an adjustment metal 17 is not provided on a substrate 101, and a third planarization film 112 is provided on a first insulating film 103. Specifically, the third planarization film 112 is provided on the first insulating film 103, and the third planarization film 112 has an opening 112a having a larger opening width than an opening 103a in the first insulating film 103.

A lower-layer lower electrode 121 and a drain electrode 13d contact each other in the opening 112a in the third planarization film 112 and in the opening 103a in the first insulating film 103.

Since the opening 112a in the third planarization film 112 is provided, portions of a photodiode 12, a third insulating film 105, and a fourth insulating film 106, the portions overlapping the opening 112a in plan view, are depressed toward the opening 112a. That is, the heights of the portions of the photodiode 12, the third insulating film 105, and the fourth insulating film 106 over the opening 112a are smaller than the heights of other portions of the photodiode 12, the third insulating film 105, and the fourth insulating film 106. Hence, the height of the fourth insulating film 106 over the opening 112a from the surface of the substrate 101 becomes substantially the same as the height of the fourth insulating film 106 over the relay wire 122 from the surface of the substrate 101. A contact hole CH21 on the photodiode 12 is provided at a position that overlaps the opening 112a in the third planarization film 112 in plan view. Hence, the film thickness of a photoresist 200 (see FIG. 5L and so on) that is applied in order to form the contact hole CH21 and a contact hole CH22 can be made generally smaller than in the second and third embodiments. As a result, the amount of exposure of the photoresist 200 can be made smaller than in the second and third embodiments, the photoresist 200 in the vicinity of the side surface of the photodiode 12 is less likely to be reduced by exposure, and the photodiode 12 is less susceptible to etching damage.

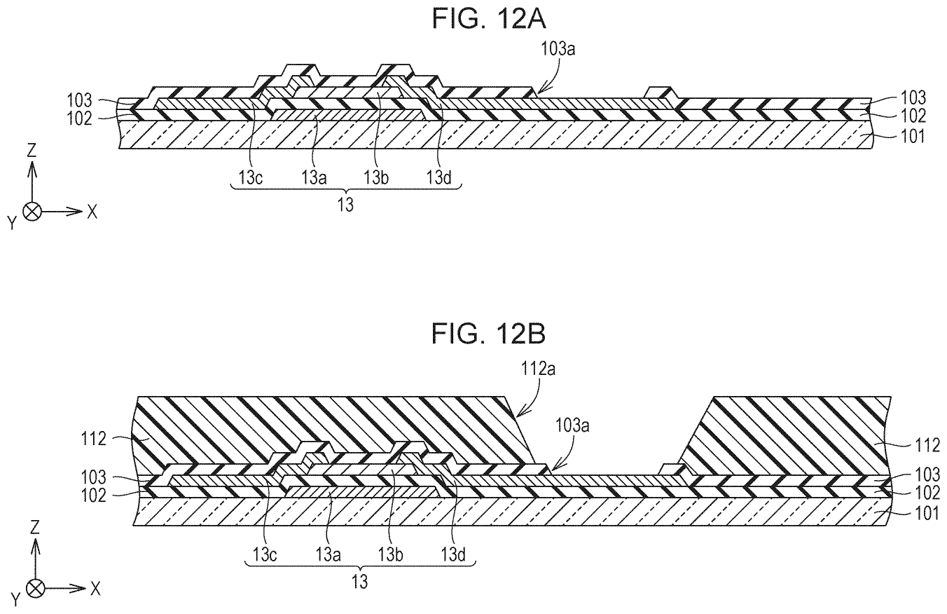

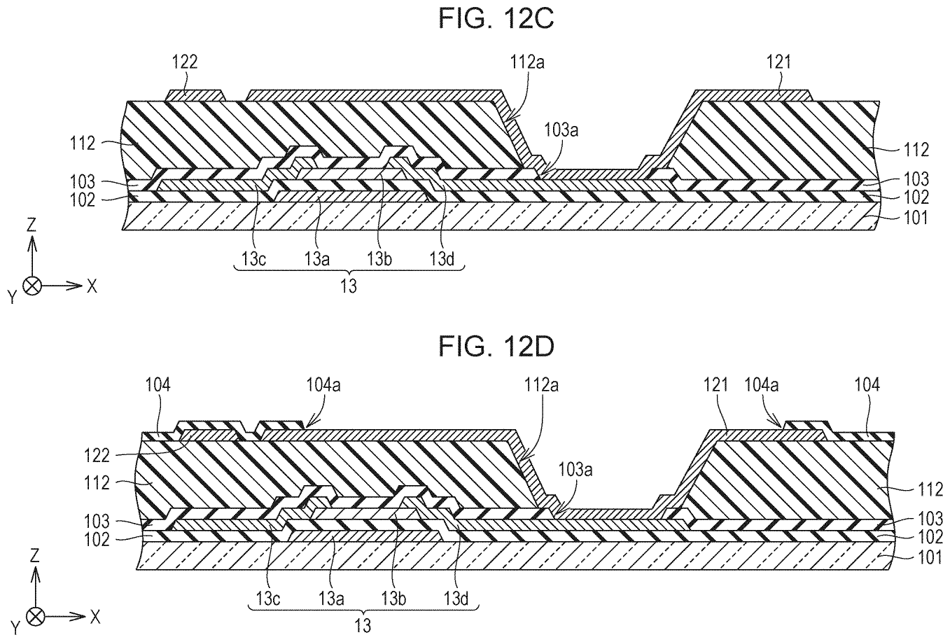

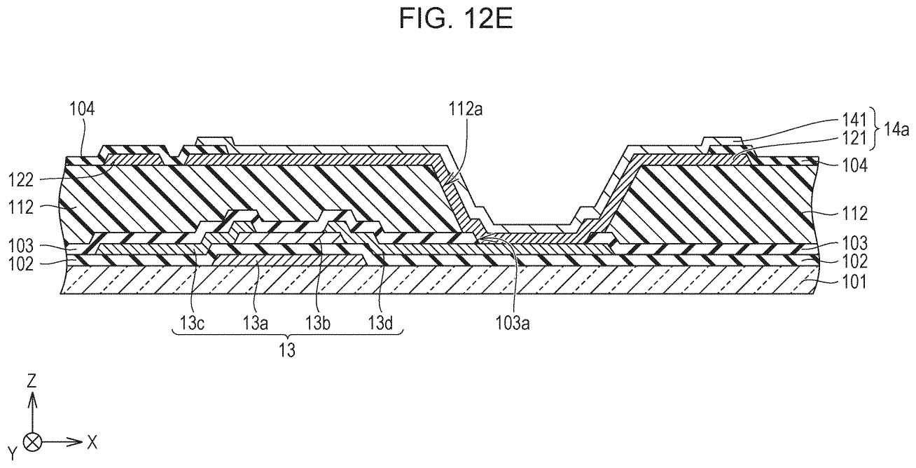

The imaging panel 1C may be fabricated by a method below. First, the same process as in FIG. 5A in the first embodiment described above is performed to form the gate electrode 13a, and then the same processes as in FIGS. 5B and 5C are performed. As a result, the opening 103a in the first insulating film 103 is formed on the drain electrode 13d of the TFT 13 (see FIG. 12A).

Next, using a photolithography method, the third planarization film 112 made of a photosensitive acryl-based resin is formed on the first insulating film 103. As a result, the opening 112a in the third planarization film 112, the opening width of the opening 112a being larger than that of the opening 103a in the first insulating film 103, is formed (see FIG. 12B).

Subsequently, the same process as in FIG. 5D in the first embodiment is performed to form the relay wire 122 and the lower-layer lower electrode 121 on the third planarization film 112 (see FIG. 12C). Then, the same process as in FIG. 5E in the first embodiment is performed to form a second insulating film 104 (see FIG. 12D), and subsequently, the same process as in FIG. 5F in the first embodiment is performed to form an upper-layer lower electrode 141 (see FIG. 12E). Thereafter, the same processes as in FIGS. 5G to 5O in the first embodiment are performed to thereby fabricate the imaging panel 1C.

Although the embodiments have been described above, the above-described embodiments are merely exemplary for implementing the present disclosure. Hence, the present disclosure is not limited to the above-described embodiments, and the above-described embodiments can be modified as appropriate and be implemented within the scope that does not depart from the spirit thereof.

(1) Although an example in which the adjustment metal 17 is constituted by the same material as that of the gate electrode 13a of the TFT 13 has been described in the first to third embodiments described above, the material that constitutes the adjustment metal 17 may be constituted by the same material as that of the source electrode 13c and the drain electrode 13d or may be constituted by another material.

(2) In the above-described embodiments, an X-ray imaging panel can be fabricated by forming the scintillator 4 on the active matrix substrate 1 so as to cover an imaging area of the active matrix substrate 1.

The above-described imaging panel can be explained in the following manner.

An imaging panel according to a first configuration includes: a substrate; a photoelectric converting element provided on the substrate; a first wiring layer that does not overlap the photoelectric converting element in plan view and that is provided more adjacent to the substrate than an anode of the photoelectric converting element; a second wiring layer provided at an opposite side to the substrate with respect to the photoelectric converting element; a first insulating layer that is provided between the first wiring layer and the second wiring layer and that overlaps the photoelectric converting element and the first wiring layer in plan view; a first opening that penetrates the first insulating layer to provide connection between the first wiring layer and the second wiring layer; a second opening that penetrates the first insulating layer to provide connection between the anode and the second wiring layer; and an adjustment metal layer that overlaps the first opening in plan view and that is provided more adjacent to the substrate than the first wiring layer. The adjustment metal layer is electrically independently provided on the substrate.

According to the first configuration, the first wiring layer is provided at a position that does not overlap the photoelectric converting element on the substrate in plan view and more adjacent to the substrate than the anode of the photoelectric converting element, and the second wiring layer is provided at an opposite side to the substrate with respect to the photoelectric converting element. Also, the first insulating layer provided between the first wiring layer and the second wiring layer overlaps the first wiring layer and the photoelectric converting element in plan view. The first opening penetrates the first insulating layer over the first wire, and the second opening penetrates the first insulating layer over the anode of the photoelectric converting element. In the first opening, the first wiring layer and the second wiring layer are connected to each other, and in the second opening, the second wiring layer and the anode are connected to each other. Since the first opening and the second opening penetrate the same first insulating layer, the first opening and the second opening can be fabricated at the same time, for example, by using a photolithography method in a process of fabricating the imaging panel.

The height of the first insulating layer from the substrate is larger at the second opening side at which the photoelectric converting element is provided. In the first configuration, an electrically independent adjustment metal layer is provided on the substrate, at a position that overlaps the first opening in plan view, and more adjacent to the substrate side than the first wiring layer. Thus, compared with a case in which the adjustment metal layer is not provided, the height of the first insulating layer provided at a position that overlaps the first wiring layer in plan view from the substrate increases according to the film thickness of the adjustment metal layer, and a difference between that height of the first insulating layer and the height of the first insulating layer at a position that overlaps the anode in plan view from the substrate decreases. Hence, the film thickness of the photoresist at the first opening side, the photoresist being applied to the first insulating layer in order to form the first opening and the second opening, is smaller than a case in which the adjustment metal layer is not provided. As a result, the amount of exposure of the photoresist used to form the first opening and the second opening is reduced, the photoresist in the vicinity of the side surface of the photoelectric converting element is less likely to be reduced by exposure, and the photoelectric converting element is less susceptible to etching damage. Hence, dark current in the photoelectric converting element in the imaging panel is less likely to increase.

The imaging panel may further include a switching element provided on the substrate in the first configuration and more adjacent to the substrate than the first wiring layer. The adjustment metal layer may be formed of material that is the same as at least part that constitutes the switching element (a second configuration).

According to the second configuration, the adjustment metal layer can be formed in a process in which the switching element is formed.

In the second configuration, the adjustment metal layer may be provided in contact with the substrate; the switching element may include a gate provided in a same layer as the adjustment metal layer; the imaging panel may further include a second insulating layer that covers the gate and the adjustment metal layer; and a cathode of the photoelectric converting element may be in contact with the substrate (a third configuration).

In the third configuration, although the second insulating layer is provided on the substrate and in an area where the adjustment metal layer and the gate of the switching element are provided, the second insulating layer is not provided in an area where the photoelectric converting element is provided, and the cathode of the photoelectric converting element is in direct contact with the substrate. Thus, the difference between the heights of the first wiring layer and the first insulating layer that overlap the adjustment metal layer in plan view from the substrate and the height of the first insulating layer that overlaps the anode of the photoelectric converting element in plan view from the substrate decreases. As a result, it is possible to further reduce the amount of exposure of the photoresist used to form the first opening and the second opening.

In the second configuration, the imaging panel may further include a third insulating layer that is provided in contact with the substrate and that overlaps the adjustment metal layer in plan view, and a cathode of the photoelectric converting element may be in contact with the substrate (a fourth configuration).

According to the fourth configuration, although the third insulating layer that is in direct contact with the substrate overlaps the adjustment metal layer in plan view, the cathode of the photoelectric converting element is provided on the substrate at the photoelectric converting element side, and the third insulating layer is not provided thereat. Thus, the difference between the heights of the first wiring layer and the first insulating layer that overlap the adjustment metal layer in plan view from the substrate and the height of the first insulating layer that overlaps the anode of the photoelectric converting element in plan view from the substrate decreases. As a result, it is possible to further reduce the amount of exposure of the photoresist used to form the first opening and the second opening.

An imaging panel according to a fifth configuration includes: a substrate; a photoelectric converting element provided on the substrate; a first wiring layer that does not overlap the photoelectric converting element in plan view and that is provided more adjacent to the substrate than an anode of the photoelectric converting element; a second wiring layer provided in a layer at an opposite side to the substrate with respect to the photoelectric converting element; an insulating layer that is provided between the first wiring layer and the second wiring layer and that overlaps the photoelectric converting element and the first wiring layer in plan view; a first opening that penetrates the insulating layer to provide connection between the first wiring layer and the second wiring layer; a second opening that penetrates the insulating layer to provide connection between the anode and the second wiring layer; and a planarization film provided between a cathode of the photoelectric converting element and the substrate. The planarization film has a third opening in an area that overlaps the second opening in plan view; and a portion of the photoelectric converting element, the portion overlapping the third opening in plan view, is closer in distance to the substrate than another portion of the photoelectric converting element.

According to the fifth configuration, the first wiring layer is provided at a position that does not overlap the photoelectric converting element on the substrate in plan view and more adjacent to the substrate than the anode of the photoelectric converting element, and the second wiring layer is provided at an opposite side to the substrate with respect to the photoelectric converting element. Also, the insulating layer provided between the first wiring layer and the second wiring layer overlaps the first wiring layer and the photoelectric converting element in plan view. The first opening penetrates the insulating layer over the first wire, and the second opening penetrates the insulating layer over the anode of the photoelectric converting element. In the first opening, the first wiring layer and the second wiring layer are connected to each other, and in the second opening, the second wiring layer and the anode are connected to each other. Since the first opening and the second opening penetrate the same insulating layer, the first opening and the second opening can be fabricated at the same time by using a photolithography method in a process of fabricating the imaging panel.

The height of the insulating layer from the substrate is larger at the second opening side where the photoelectric converting element is provided. In the fifth configuration, the planarization film having the third opening in an area that overlaps the second opening in plan view is provided between the cathode of the photoelectric converting element and the substrate. Since the third opening in the planarization film is provided at the second opening side, a portion of the photoelectric converting element, the portion overlapping the third opening in plan view, becomes closer to the substrate. Thus, compared with a case in which the third opening in the planarization film is not provided, the difference between the height of the insulating layer at a position that overlaps the first wiring layer in plan view and the height of the insulating layer at a position that overlaps the anode in plan view decreases. Hence, the difference between the film thickness of the photoresist at the first opening side and the film thickness of the photoresist at the second opening side, the photoresist being applied to the insulating layer in order to form the first opening and the second opening, decreases. As a result, compared with a case in which the third opening in the planarization film is not provided, the amount of exposure of the photoresist used to form the first opening and the second opening can be reduced, and the photoresist in the vicinity of the side surface of the photoelectric converting element is less likely to be reduced by exposure. Hence, the photoelectric converting element is less susceptible to etching damage, and dark current in the photoelectric converting element is less likely to increase.

The imaging panel may further include a switching element that is provided on the substrate in the fifth configuration and between the planarization film and the substrate and that overlaps the photoelectric converting element in plan view, and the switching element may include a drain that is connected to the cathode of the photoelectric converting element in the third opening (a sixth configuration).

According to the sixth configuration, the photoelectric converting element and the switching element are arranged so as to overlap each other in plan view, and the cathode of the photoelectric converting element and the drain of the switching element are connected in the third opening. Thus, compared with a case in which the photoelectric converting element and the switching element are provided so as not to overlap each other in plan view, it is possible to increase the resolution of the imaging panel.

The present disclosure contains subject matter related to that disclosed in U.S. Provisional Patent Application No. 62/878,773 filed in the U.S. Patent Office on Jul. 26, 2019, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An imaging panel comprising:
a substrate;
a photoelectric converting element provided on the substrate;
a first wiring layer that does not overlap the photoelectric converting element in plan view and that is provided more adjacent to the substrate than an anode of the photoelectric converting element;
a second wiring layer provided at an opposite side to the substrate with respect to the photoelectric converting element;
a first insulating layer that is provided between the first wiring layer and the second wiring layer and that overlaps the photoelectric converting element and the first wiring layer in plan view;
a first opening that penetrates the first insulating layer to provide connection between the first wiring layer and the second wiring layer;
a second opening that penetrates the first insulating layer to provide connection between the anode and the second wiring layer; and
an adjustment metal layer that overlaps the first opening in plan view and that is provided more adjacent to the substrate than the first wiring layer,
wherein the adjustment metal layer is electrically independently provided on the substrate.

2. The imaging panel according to claim 1, further comprising:
a switching element provided on the substrate and more adjacent to the substrate than the first wiring layer,
wherein the adjustment metal layer comprises material that is the same as at least part that constitutes the switching element.

3. The imaging panel according to claim 2,
wherein the adjustment metal layer is provided in contact with the substrate;
the switching element includes a gate provided in a same layer as the adjustment metal layer;
the imaging panel further comprises a second insulating layer that covers the gate and the adjustment metal layer; and
a cathode of the photoelectric converting element is in contact with the substrate.

4. The imaging panel according to claim 2, further comprising:
a third insulating layer that is provided in contact with the substrate and that overlaps the adjustment metal layer in plan view,
wherein a cathode of the photoelectric converting element is in contact with the substrate.

5. An imaging panel comprising:
a substrate;
a photoelectric converting element provided on the substrate;
a first wiring layer that does not overlap the photoelectric converting element in plan view and that is provided more adjacent to the substrate than an anode of the photoelectric converting element;
a second wiring layer provided in a layer at an opposite side to the substrate with respect to the photoelectric converting element;
an insulating layer that is provided between the first wiring layer and the second wiring layer and that overlaps the photoelectric converting element and the first wiring layer in plan view;
a first opening that penetrates the insulating layer to provide connection between the first wiring layer and the second wiring layer;
a second opening that penetrates the insulating layer to provide connection between the anode and the second wiring layer; and
a planarization film provided between a cathode of the photoelectric converting element and the substrate,
wherein the planarization film has a third opening in an area that overlaps the second opening in plan view; and
a portion of the photoelectric converting element, the portion overlapping the third opening in plan view, is closer in distance to the substrate than another portion of the photoelectric converting element.

6. The imaging panel according to claim 5, further comprising:
a switching element that is provided on the substrate and between the planarization film and the substrate and that overlaps the photoelectric converting element in plan view,
wherein the switching element includes a drain that is connected to the cathode of the photoelectric converting element in the third opening.
